(19) United States
(12) Patent Application Publication
(10) Pub. No.: US 2026/0040807 A1
(43) Pub. Date: Feb. 5, 2026

(54) PEELING DEVICE FOR DISPLAY DEVICE AND METHOD FOR DISPLAY DEVICE

(71) Applicants: Samsung Display Co., LTD., Yongin-si (KR); ULVAC, INC., Chigasaki-shi (JP)

(72) Inventors: Kyung Hoon CHUNG, Yongin-si (KR); Shuji OSONO, Chigasaki-shi (JP); Ho Seop LEE, Chigasaki-shi (JP); Kazuhiko KOIZUMI, Chigasaki-shi (JP); Jung Seob LEE, Yongin-si (KR); Yong Sic JEON, Yongin-si (KR); Hyeon Sik KIM, Yongin-si (KR); Yong YEO, Yongin-si (KR)

(21) Appl. No.: 19/187,393

(22) Filed: Apr. 23, 2025

(30) Foreign Application Priority Data
Jul. 31, 2024 (KR) 10-2024-0101679

(51) Int. Cl. H10K 71/80; H10K 71/16; H10K 71/50

(52) U.S. Cl. CPC H10K 71/80; H10K 71/50; H10K 71/166

(57) ABSTRACT

A peeling device includes: a transport unit; a carrier movable on and along the transport unit and having a substrate tray accommodated therein; a rotatable peeling stage disposed on the transport unit; a support disposed on the peeling stage and movable on the peeling stage along an upstream direction of the transport unit, a downstream direction of the transport unit, a downward direction toward the peeling stage, and an upward direction opposite to the downward direction, and rotatable in a first rotation direction, and a second rotation direction opposite to the first rotation direction; a gripper connected to the support so as to be disposed between the support and the peeling stage; and a static eliminator disposed on a side of the peeling stage.

This application claims priority to Korean Patent Application No. 10-2024-0101679, filed on Jul. 31, 2024, and all the benefits accruing therefrom under 35 U.S.C. § 119, the content of which in its entirety is herein incorporated by reference.

### BACKGROUND

### 1. Field

An embodiment relates to a manufacturing device for a display device, and more particularly, to a peeling device and peeling method for display device, by which a substrate can be easily separated from an electrostatic chuck.

### 2. Description of the Related Art

Organic light emitting diode displays have self-luminous characteristics and, unlike liquid crystal displays, do not require a separate light source and thus can be reduced in thickness and weight. In addition, organic light emitting diode displays are attracting attention as next-generation displays for portable electronic devices due to their high-quality characteristics such as low power consumption, high luminance, and high response speed.

### SUMMARY

Aspects of the present disclosure provide a peeling device and peeling method for display device, by which a substrate can be easily separated from an electrostatic chuck.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a peeling device for a display device. The peeling device includes: a transport unit; a carrier movable on and along the transport unit and having a substrate tray accommodated therein; a rotatable peeling stage disposed on the transport unit; a support disposed on the peeling stage and movable on the peeling stage along an upstream direction of the transport unit, a downstream direction of the transport unit, a downward direction toward the peeling stage, and an upward direction opposite to the downward direction, and rotatable in a first rotation direction, and a second rotation direction opposite to the first rotation direction; a gripper connected to the support so as to be disposed between the support and the peeling stage; and a static eliminator disposed on a side of the peeling stage.

According to another aspect of the present disclosure, there is provided a peeling method for a display device. The peeling method includes: preparing a peeling device for a display device, wherein the peeling device includes a transport unit, a carrier movable on and along the transport unit and having a substrate tray accommodated therein, a rotatable peeling stage disposed on the transport unit, a support disposed on the peeling stage and movable on the peeling stage along an upstream direction of the transport unit, a downstream direction of the transport unit, a downward direction toward the peeling stage, and an upward direction opposite to the downward direction, and rotatable in a first rotation direction, and a second rotation direction opposite to the first rotation direction, a gripper connected to the support so as to be disposed between the support and the peeling stage, and a static eliminator disposed on a side of the peeling stage; placing the carrier, in which the substrate tray and a substrate on an electrostatic chuck of the substrate tray are accommodated, on the transport unit; rotating the peeling stage with respect to a first side of the peeling stage facing the carrier in the first rotation direction so that a second side of the peeling stage opposite to the first side is lifted in the upward direction; inserting the gripper into a second hole of the substrate tray among a first hole of the substrate tray in the upstream direction and the second hole of the substrate tray in the downstream direction; overlapping the gripper and a lower surface of the substrate by moving the gripper inserted into the second hole in the upstream direction within the second hole; opening a first clamp and a second clamp of the substrate tray to release a constraining force of the first clamp and the second clamp applied to a first side of the substrate and a second side of the substrate; lifting the first side of the substrate from the electrostatic chuck through the gripper by moving the gripper out of the second hole by raising the support; and providing ions between the electrostatic chuck and the substrate through a nozzle of the static eliminator which is disposed at an edge of the peeling stage in the upstream direction.

According to a peeling device peeling method for display device according to an embodiment, a substrate can be easily separated from an electrostatic chuck through a static eliminator.

However, effects according to the embodiments of the present disclosure are not limited to those exemplified above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic diagram of a deposition device according to an embodiment;

FIG. 2 is a perspective view of a substrate tray of FIG. 1;

FIG. 3 is a perspective view of a carrier disposed on a transport track;

FIG. 4 illustrates a state where the substrate tray of FIG. 2 is coupled to the carrier of FIG. 3;

FIG. 5 is a perspective view of a peeling device for a display device according to an embodiment;

FIG. 6 is a cross-sectional view of a support and a gripper according to an embodiment;

FIG. 7 is a schematic diagram of a peeling stage and a static eliminator according to an embodiment; and

FIGS. 8, 9, 10, 11, 12, 13, 14, 15, 16, 17, 18, 19, 20 and 21 are views for explaining a peeling method using a peeling device for a display device according to an embodiment.

FIG. 22 is a block diagram of an electronic device according to one embodiment.

FIGS. 23, 24 and 25 are schematic diagrams of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, specific exemplary embodiments will be described with reference to the accompanying drawings.

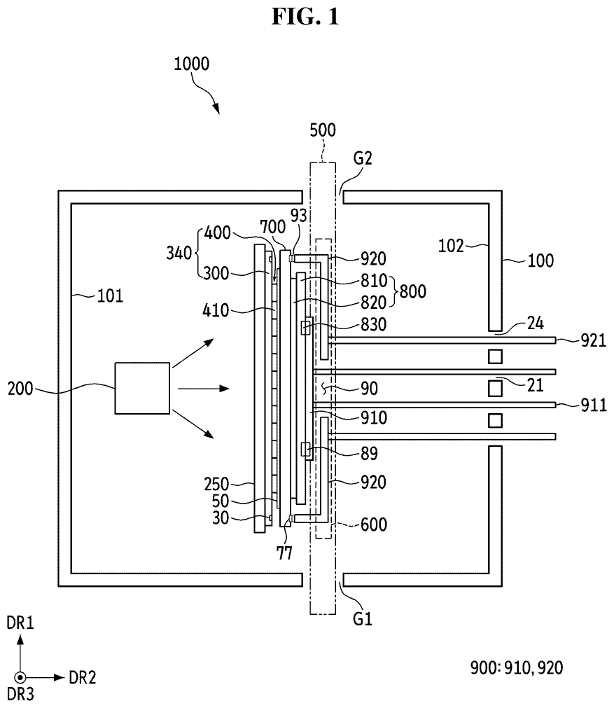

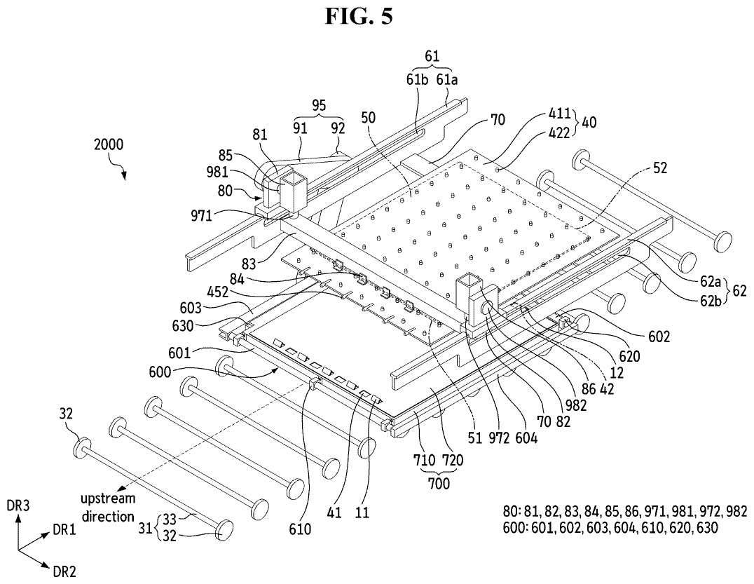

A manufacturing device for a display device according to an embodiment may include a deposition device 1000 of FIG. 1 (e.g., a deposition device for a substrate for a display device), a peeling device 2000 of FIG. 5 (e.g., a device for peeling a substrate for a display device from a substrate tray), and a position changing device (e.g., a device for changing the position of a carrier for manufacturing a display device).

FIG. 1 is a schematic diagram of a deposition device 1000 according to an embodiment. In FIG. 1, a direction (hereinafter, referred to as a “third reverse direction”) opposite to a third direction DR3 may be the direction of gravity.

The deposition device 1000 for a display device according to the embodiment may include a chamber 100, a deposition source 200, a deposition stage 250, a mask structure 340, a substrate tray 700, a magnet plate 800, a transport track 500, a carrier 600, and a driving mechanism 900 as illustrated in FIG. 1.

The chamber 100 may define a deposition space in which a deposition process is performed. A layer deposition process for manufacturing an organic light emitting diode display device may be performed inside the chamber 100. The chamber 100 may be a vacuum chamber 100. The deposition source 200, the deposition stage 250, the driving mechanism 900, and a portion of the transport track 500 described above may be disposed inside the chamber 100. When a deposition process is in progress, the deposition source 200, the deposition stage 250, the mask structure 340, a substrate 50, the substrate tray 700, the magnet plate 800, a portion of the transport track 500, and the driving mechanism 900 may be disposed inside the chamber 100.

The deposition source 200 may be disposed inside the chamber 100. For example, the deposition source 200 may be disposed between a first inner wall 101 of the chamber 100 and the deposition stage 250. The deposition source 200 may provide a deposition material. The deposition material from the deposition source 200 may pass through an opening of the deposition stage 250 and move toward the mask structure 340. Specifically, the deposition source 200 may evaporate a deposition material such as an organic material or an electrode material by heating the deposition material to a high temperature, and the evaporated deposition material may be deposited on the substrate 50 through pattern holes of the mask structure 340. The organic material may be, for example, a material for manufacturing a hole injection layer, a hole transport layer, a light emitting layer, an electron transport layer, and an electron injection layer disposed between an anode and a cathode of an organic light emitting diode. The substrate 50 may be, for example, a substrate used in a display device including organic light emitting diodes.

The deposition stage 250 may be disposed above the deposition source 200. For example, the deposition stage 250 may be disposed between the deposition source 200 and the mask structure 340. The deposition stage 250 may be disposed in a fixed state inside the chamber 100. The deposition stage 250 may be tilted toward the deposition source 200. For example, the deposition stage 250 may be tilted in a direction (hereinafter, referred to as a “second reverse direction”) opposite to a second direction DR2 from the third direction DR3. Accordingly, an angle formed between a surface of the deposition stage 250 which faces the deposition source 200 and the ground (e.g., a bottom surface of the chamber 100) on which the deposition stage 250 is disposed may be an acute angle. Here, supports may be disposed on a lower side of the deposition stage 250 to protrude from a surface of the lower side along the second direction DR2. The deposition stage 250 may be shaped like a quadrangular frame with a penetrated central portion. For example, the deposition stage 250 may have an opening in the central portion.

The mask structure 340 may be disposed on the deposition stage 250. For example, the mask structure 340 may be disposed between the deposition stage 250 and the substrate tray 700. The mask structure 340 may be disposed on the supports of the deposition stage 250. Here, since the deposition stage 250 is tilted, the mask structure 340 may also be tilted on the deposition stage 250. The mask structure 340 may include a frame 300 and a mask 400.

The frame 300 may be disposed on the deposition stage 250. For example, the frame 300 may be disposed between the deposition stage 250 and the mask 400. The frame 300 may be shaped like a quadrangular frame with a penetrated central portion. For example, the frame 300 may have an opening in the central portion. Grooves 30 may be disposed at both edges of the frame 300. The frame 300 may include a magnetic material. For example, the frame 300 may include a material (e.g., iron (Fe)) that can be attracted to a magnet.

The mask 400 may be disposed on the frame 300. For example, the mask 400 may be disposed between the frame 300 and the substrate tray 700. The mask 400 may be disposed on the frame 300 to cover the opening of the frame 300. Edges of the mask 400 may be attached to the frame 300. For example, the mask 400 may be attached to the frame 300 by welding. The mask 400 may be a fine metal mask (FMM).

The mask 400 may include a plurality of sub-masks 410 (or mask sticks). Each of the sub-masks 410 may have a rectangular shape extending in the third direction DR3. The sub-masks 410 may be arranged along a first direction DR1. Adjacent sub-masks 410 may contact each other. Each sub-mask 410 excluding both edges may be disposed on the opening 39 of the frame 300. Although not illustrated, each sub-mask 410 may have a plurality of pattern holes penetrating the sub-mask 410 in the second direction DR2. A deposition material from the deposition source 200 may be deposited on the substrate 50 through the pattern holes of each sub-mask 410. Each sub-mask 410 may be made of a material including a magnetic material (e.g., iron (Fe)). For example, each sub-mask 410 may include a material that is attracted to a magnet.

The substrate tray 700 may be disposed on the mask structure 340. For example, the substrate tray 700 may be disposed between the mask 400 of the mask structure 340 and the magnet plate 800. The substrate tray 700 may transport the substrate 50. Here, the substrate tray 700 may adsorb the substrate 50 using an electrostatic force. For example, the substrate tray 700 may provide a surface on which the substrate 50 is placed while serving as an electrostatic chuck which adsorbs and fixes the substrate 50 to the surface of the substrate tray 700. The substrate tray 700 may be made of a material including ceramic or titanium.

The magnet plate 800 may be disposed on the substrate tray 700. For example, the magnet plate 800 may be disposed between the substrate tray 700 and the driving mechanism 900. The magnet plate 800 may be disposed on the substrate tray 700 to face the substrate tray 700. The magnet plate 800 may provide a magnetic force. For example, the magnet plate 800 may provide a magnetic force so that the metal mask 400 described above is closely attached to the substrate 50.

The magnet plate 800 may include a base member 810 and a plurality of magnets 820 disposed on the base member 810. For example, the magnets 820 may be disposed on the base member 810. As a specific example, when a side surface of the base member 810 which faces the substrate tray 700 is defined as a first surface, the magnets 820 may be disposed on the first surface of the base member 810. Each magnet 820 may include, for example, a permanent magnet.

Each of the magnets 820 may have an N pole and an S pole. A plurality of magnets 820 disposed along the first direction DR1 may be disposed such that opposite polarities face each other in the first direction DR1. A plurality of magnets 820 disposed along the second direction DR2 may be disposed such that opposite polarities face each other.

When a surface opposite the first surface of the base member 810 is defined as a second surface of the base member 810, a plurality of magnetic objects 830 may be disposed on the second surface of the base member 810. For example, the magnetic objects 830 may be disposed on the second surface in coupling grooves of the base member 810. For example, the magnetic objects 830 may include a material (e.g., iron (Fe)) that can be attracted to a magnet.

The driving mechanism 900 may include a first driving mechanism 910 and a second driving mechanism 920.

The first driving mechanism 910 may be disposed between the magnet plate 800 and the second driving mechanism 920. For example, the first driving mechanism 910 may be disposed between the base member 810 of the magnet plate 800 and the second driving mechanism 920. The first driving mechanism 910 may include magnets 89. For example, the magnets 89 may be disposed on a surface opposite a surface of the first driving mechanism 910 which is connected to a first driving shaft 911. The magnets 89 of the first driving mechanism 910 may correspond to (or overlap) the magnetic objects 830 of the magnet plate 800. The magnets 89 may include permanent magnets.

The magnet plate 800 may be detachably attached to the first driving mechanism 910. For example, the base member 810 of the magnet plate 800 may be detachably attached to the magnets 89 of the first driving mechanism 910. In other words, the magnetic objects 830 of the base member 810 may be attached to the magnets 89 of the first driving mechanism 910 by a magnetic force from the magnets 89 of the first driving mechanism 910. The first driving mechanism 910 may move toward the deposition source 200 or in the opposite direction within the chamber 100. For example, the first driving mechanism 910 may move along the second reverse direction or the second direction DR2. To this end, according to an embodiment, the first driving mechanism 910 may be connected to the first driving shaft 911 which is extended along the second reverse direction or retracted along the second direction DR2. The first driving shaft 911 may be connected to an external driver through a hole 90 of the second driving mechanism 920 and a hole 21 of the chamber 100. In addition, the first driving mechanism 910 may move further in the first direction DR1, a first reverse direction (i.e., a direction opposite to the first direction DR1), the third direction DR3, or the third reverse direction. In this case, the first driving shaft 911 may move further in the first direction DR1, the first reverse direction, the third direction DR3, or the third reverse direction. The movement of the magnet plate 800 attached to the first driving mechanism 910 may be controlled by the movement of the first driving mechanism 910.

The second driving mechanism 920 may be disposed between the first driving mechanism 910 and a second inner wall 102 of the chamber 100. The second driving mechanism 920 may include electro-permanent magnets 93. The substrate tray 700 may be attached to the second driving mechanism 920. For example, the substrate tray 700 may be attached to the second driving mechanism 920 as magnetic objects 77 of the substrate tray 700 are attached to the electro-permanent magnets 93 of the second driving mechanism 920. The electro-permanent magnets 93 may be disposed at both edges of the second driving mechanism 920. The magnetic objects 77 may be disposed at both edges of the substrate tray 700 to correspond to the electro-permanent magnets 93. The magnetic objects 77 may include a magnetic material that is attracted to a magnet, such as iron (Fe).

The second driving mechanism 920 may also include electromagnets instead of the electro-permanent magnets 93. The second driving mechanism 920 may move toward the deposition source 200 or in the opposite direction within the chamber 100. For example, the second driving mechanism 920 may move along the second reverse direction or the second direction DR2. To this end, according to an embodiment, the second driving mechanism 920 may be connected to a second driving shaft 921 which is extended along the second reverse direction or retracted along the second direction DR2. In addition, the second driving mechanism 920 may move further in the first direction DR1, the first reverse direction, the third direction DR3, or the third reverse direction. In this case, the second driving shaft 921 may move further in the first direction DR1, the first reverse direction, the third direction DR3, or the third reverse direction. The movement of the substrate tray 700 attached to the second driving mechanism 920 may be controlled by the movement of the second driving mechanism 920. The second driving mechanism 920 may perform an alignment operation between the substrate 50 of the substrate tray 700 and the mask structure 340 by controlling the position of the substrate tray 700 attached to the second driving mechanism 920.

The transport track 500 may be, for example, disposed inside the chamber 100 and outside the chamber 100 to pass through a first gate G1 and a second gate G2 of the chamber 100. The transport track 500 may extend along the first direction DR1. The first gate G1 and the second gate G2 may face each other.

The carrier 600 may move along the transport track 500. For example, the carrier 600 may move along the transport track 500 in a magnetic levitation manner. The carrier 600 may transport the substrate tray 700.

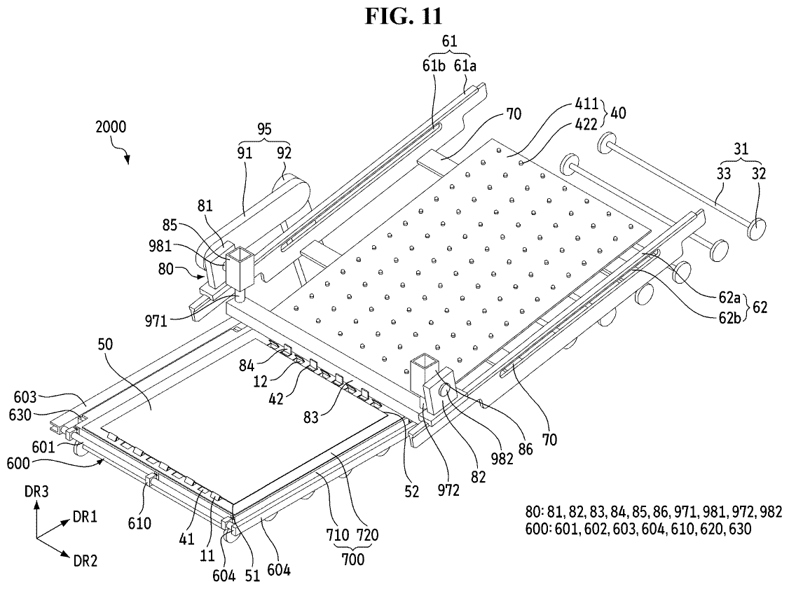

As described above, an upper side of the deposition stage 250 may be tilted toward the deposition source 200 (e.g., tilted at the same angle as the carrier 600 illustrated in FIG. 11 to be described later). Accordingly, the mask structure 340, the substrate tray 700, the substrate 50, the magnet plate 800, the first driving mechanism 910, the second driving mechanism 920, the transport track 500, and the carrier 600 described above may also be tilted at the same angle as the deposition stage 250. Accordingly, particles generated during a deposition process on the substrate 50 may fall in the direction of gravity without sticking to the substrate 50. Therefore, the substrate 50 can be prevented from being contaminated by the particles.

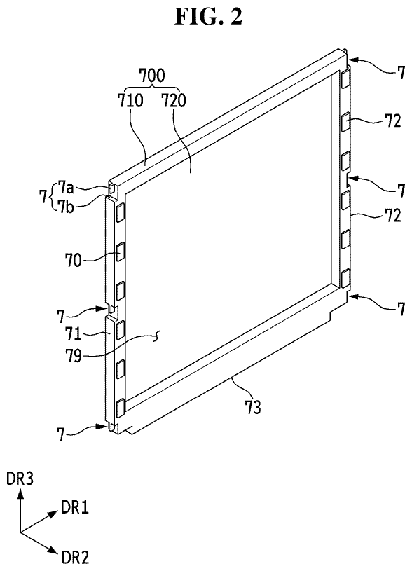

FIG. 2 is a perspective view of the substrate tray 700 of FIG. 1.

As illustrated in FIG. 2, the substrate tray 700 may include a support plate 710 and an electrostatic chuck 720.

The support plate 710 may be shaped like a quadrangular frame with a penetrated central portion. For example, the support plate 710 may have an opening 79 in the central portion.

The electrostatic chuck 720 may be disposed on the support plate 710. For example, the electrostatic chuck 720 may be disposed between the support plate 710 and the substrate 50. Here, the electrostatic chuck 720 may cover the opening 79 of the support plate 710. The substrate 50 may be placed on the electrostatic chuck 720. The electrostatic chuck 720 may adsorb the substrate 50 using an electrostatic force.

At least one detachable member 7 may be disposed at edges of the substrate tray 700. For example, a detachable member 7 may be disposed near each corner of the quadrangular support plate 710. Specifically, the support plate 710 may have six detachable members 7. Here, three of the six detachable members 7 may be disposed at the top, middle and bottom of a first side 71 of the substrate tray 700, respectively, and the remaining three detachable members 7 may be disposed at the top, middle and bottom of a second side 72 of the substrate tray 700, respectively. The first side 71 and the second side 72 of the substrate tray 700 may face each other along the first direction DR1.

Each detachable member 7 may include a coupling tip 7a and a separation groove 7b disposed adjacent to each other in the third direction DR3. The coupling tip 7a may be disposed higher than the separation groove 7b. For example, in one detachable member 7, the coupling tip 7a may be disposed higher than the separation groove 7b in the third direction DR3. The coupling tip 7a may have a smaller thickness (e.g., size in the second direction DR2) than other parts of the substrate tray 700. For example, the coupling tip 7a may have a smaller thickness (e.g., size in the second direction DR2) than other parts of the support plate 710. The separation groove 7b may be recessed from the first side 71 of the substrate tray 700 (e.g., the support plate 710) toward the second side 72 or may be recessed from the second side 72 toward the first side 71. For example, separation grooves 7b disposed on different sides and facing each other may be recessed toward each other.

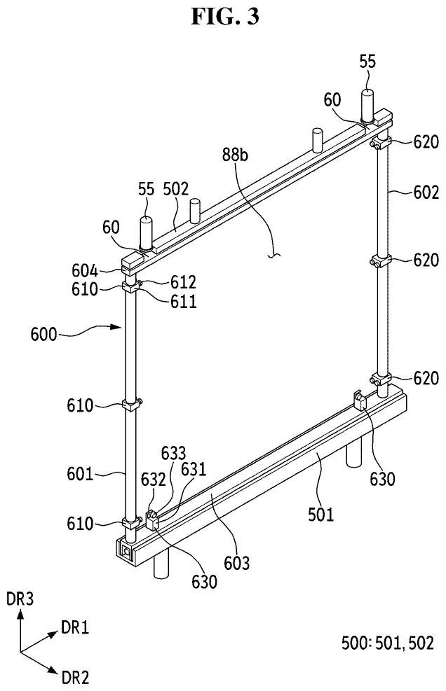

FIG. 3 is a perspective view of a carrier disposed on a transport track. Here, FIG. 3 may be a perspective view of the carrier 600 disposed on the transport track 500 of FIG. 1.

The carrier 600 may move along the transport track 500. The transport track 500 may include a lower track 501 and an upper track 502 facing each other in the third direction DR3. Therefore, the carrier 600 may be disposed between the lower track 501 and the upper track 502. The carrier 600 may move along the transport track 500 between the lower track 501 and the upper track 502.

The carrier 600 may be shaped like a quadrangular frame as in the example illustrated in FIG. 3. However, the shape of the carrier 600 is not limited thereto and can be changed to various shapes.

The carrier 600 may include a plurality of bars 601, 602, 603 and 604 and a plurality of support members 610, 620 and 630 as illustrated in FIG. 3. For example, the carrier 600 may include a first bar 601, a second bar 602, a third bar 603, and a fourth bar 604 connected to each other. The substrate tray 700 may be placed in an area (e.g., an opening 88b) surrounded and defined by the first bar 601, the second bar 602, the third bar 603, and the fourth bar 604.

The first bar 601 and the second bar 602 may face each other in the first direction DR1. The third bar 603 and the fourth bar 604 may face each other in the third direction DR3. The first bar 601 may be disposed between an end of the third bar 603 and an end of the fourth bar 604. The second bar 602 may be disposed between the other end of the third bar 603 and the other end of the fourth bar 604.

The support members 610, 620 and 630 may include one or more first support members 610 extending from the first bar 601, one or more second support members 620 extending from the second bar 602, and one or more third support members 630 extending from the third bar 603.

Each of the first support members 610 may include an extension portion 611 and a plurality of protrusions 612. A side of the extension portion 611 may be connected to the first bar 601. The extension portion 611 may extend from the first bar 601 toward the second bar 602. The protrusions 612 (e.g., two protrusions 612) may be disposed on the other side of the extension portion 611. The protrusions 612 may be rotatably connected to the other side of the extension portion 611. For example, each of the protrusions 612 may rotate about an axis parallel to the first direction DR1. The protrusions 612 may face each other in the second direction DR2. Each of the protrusions 612 may have a cylindrical shape. However, the shape of the protrusions 612 is not limited thereto and can be changed to various shapes.

The second support members 620 may have the same configuration as the first support members 610 described above. However, an extension portion of each of the second support members 620 may extend from the second bar 602 toward the first bar 601.

Each of the third support members 630 may include an extension portion 631, a protruding portion 632, and a protrusion 633. A side of the extension portion 631 may be connected to the third bar 603. The extension portion 631 may extend from the third bar 603 toward the fourth bar 604. The protruding portion 632 may be disposed on the other side of the extension portion 631. The protrusion 633 may be disposed on a side of the protruding portion 632. The protrusion 633 may be rotatably connected to the side of the protruding portion 632. For example, the protrusion 633 may rotate about an axis parallel to the second direction DR2. The protrusion 633 may have a cylindrical shape. However, the shape of the protrusion 633 is not limited thereto and can be changed to various shapes.

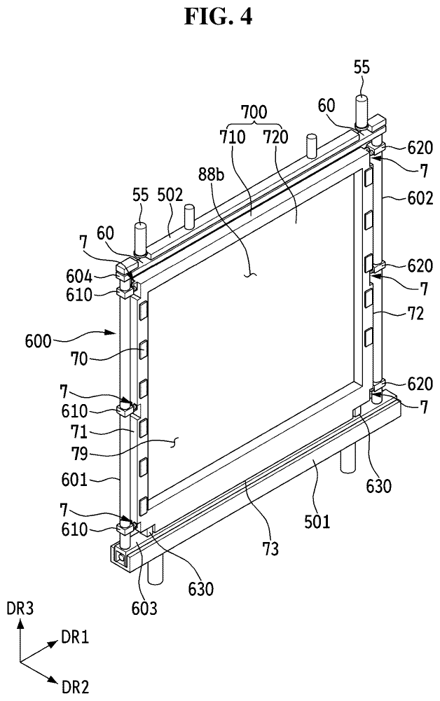

FIG. 4 illustrates a state where the substrate tray 700 of FIG. 2 is coupled to the carrier 600 of FIG. 3.

As illustrated in FIG. 4, the first support members 610, the second support members 620, and the third support members 630 may support the substrate tray 700.

Each of the first support members 610 may support the first side 71 of the substrate tray 700. For example, the first side 71 of the substrate tray 700 may be placed and supported between the protrusions 612 of each first support member 610. Specifically, the first side 71 may be supported as a coupling tip 7a of the first side 71 is placed between the protrusions 612 of each first support member 610.

Each of the second support members 620 may support the second side 72 of the substrate tray 700. For example, the second side 72 of the substrate tray 700 may be placed and supported between protrusions of each second support member 620. Specifically, the second side 72 may be supported as a coupling tip 7a of the second side 72 is placed between the protrusions of each second support member 620.

Each of the third support members 630 may support a third side 73 of the substrate tray 700. For example, the third side 73 of the substrate tray 700 may be placed and supported on the protrusion 633 of each third support member 630. Here, the protrusion 633 of each third support member 630 may contact the third side 73.

The deposition device 1000 of the embodiment may further include pushers 55. The pushers 55 may be disposed on the carrier 600. For example, the pushers 55 may be disposed on the fourth bar 604 of the carrier 600. Specifically, the pushers 55 may face the fourth bar 604 through openings 60 of the upper track 502. The pushers 55 and the openings 60 of the upper track 502 may be disposed inside the chamber 100.

The pushers 55 may move toward the fourth bar 604 or in the opposite direction. For example, the pushers 55 may move along the third reverse direction or the third direction DR3. The pushers 55 may move to a distance of a first stage and a distance of a second stage along the third reverse direction. Here, the distance of the second stage may be greater than the distance of the first stage. Here, when the pushers 55 descend to the distance of the second stage along the third reverse direction, the lower track 501 may also descend along the third reverse direction. For example, when the pushers 55 descend to the distance of the second stage, the pushers 55 and the lower track 501 may descend together in the same direction.

When the pushers 55 descend to the distance of the first stage along the third reverse direction, they may contact the carrier 600. The carrier 600 may be lowered along the third reverse direction by the pressure of the pushers 55. At this time, since the lower track 501 remains as it is without being lowered, a gap between the carrier 600 and the lower track 501 may be reduced. Accordingly, the carrier 600 can be stably placed on the lower track 501 within the chamber 100. Here, when the pushers 55 descend to the distance of the first stage, the descending distance is short. Therefore, even if the carrier 600 is lowered by the pressure of the pushers 55, the substrate tray 700 accommodated in the carrier 600 may be kept supported by the support members 610, 620 and 630 of the carrier 600.

When the pushers 55 descend to the distance of the second stage, the lower track 501 may also descend along the third reverse direction at the same time as the pushers 55. In other words, the pushers 55 and the lower track 501 may simultaneously descend along the third reverse direction. Accordingly, the carrier 600 and the lower track 501 may descend along the third reverse direction. At this time, the gap between the carrier 600 and the lower track 501 may be substantially equal to the gap between the carrier 600 and the lower track 501 when the pushers 55 descend to the distance of the first stage described above. Accordingly, the first support members 610, the second support members 620, and the third support members 630 may be moved in the third reverse direction. Therefore, the protrusions 612 of each first support member 610 and the protrusions of each second support member 620 may be placed to face each other through the separation grooves 7b of the substrate tray 700. In other words, the protrusions 612 of each first support member 610 and a corresponding coupling tip 7a of the first side 71 of the substrate tray 700 do not contact each other, and the protrusions 612 of each second support member 620 and a corresponding coupling tip of the second side 72 of the substrate tray 700 do not contact each other. In addition, as the carrier 600 is lowered along the third reverse direction by the pushers 55 as described above, the third support members 630 and the substrate tray 700 may be separated from each other. For example, since the protrusions 612 of the second support members 620 and the third side 73 of the substrate tray 700 are separated from each other, the protrusions 633 of the third support members 630 and the third side 73 do not contact each other. Accordingly, the substrate tray 700 is no longer supported by the carrier 600. Therefore, the substrate tray 700 can easily move in the second direction DR2 and the second reverse direction without being interfered with by the carrier 600.

A substrate on which a deposition process has been performed by a deposition device may be accommodated in a carrier while attached to a substrate tray. The substrate accommodated in the carrier may be unloaded from a chamber along a transport track. The carrier unloaded from the chamber may be loaded into a peeling device. For example, the carrier unloaded from the chamber may be loaded into the peeling device after its position is changed from a vertical position to a horizontal position through a position changing device. The peeling device may separate (e.g., peel) the substrate from the substrate tray accommodated in the carrier and transport the peeled substrate to another process equipment for a subsequent process.

A peeling device for a display device according to an embodiment will now be described in detail as follows with reference to the attached drawings.

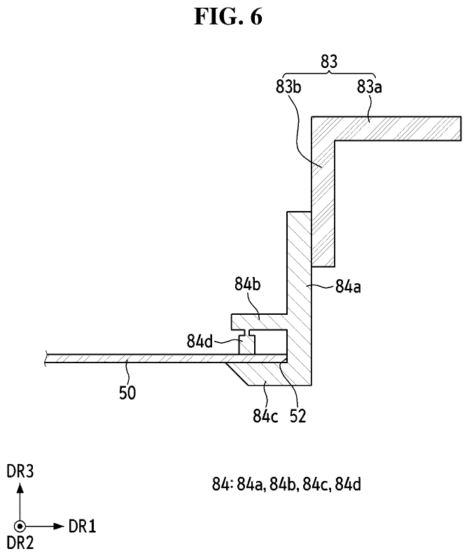

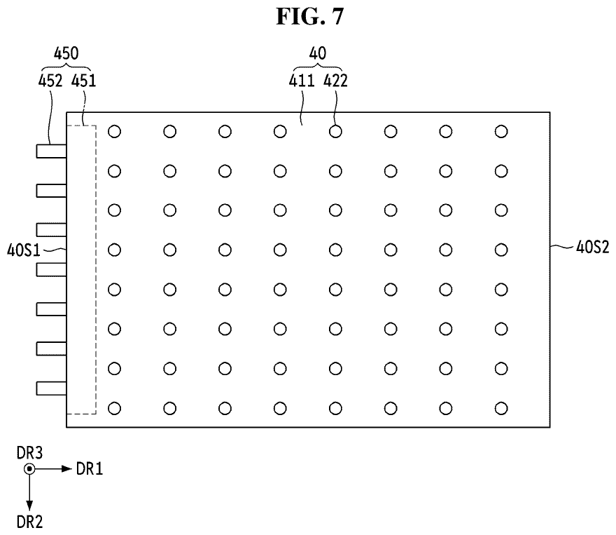

FIG. 5 is a perspective view of a peeling device 2000 for a display device according to an embodiment. FIG. 6 is a cross-sectional view of a support 83 and a gripper 84 according to an embodiment. FIG. 7 is a schematic diagram of a peeling stage 40 and a static eliminator 450 according to an embodiment. Here, the support 83 and the gripper 84 of FIG. 6 may correspond to a support 83 and a gripper 84 of FIG. 5, respectively, and the peeling stage 40 and nozzles 452 of FIG. 7 may correspond to a peeling stage 40 and nozzles 452 of FIG. 5, respectively.

The peeling device 2000 for a display device according to the embodiment may include, as illustrated in FIGS. 5 through 7, a transport unit 31, the peeling stage 40, a movable object 80, a first driving arm 95, a first guide bar 61, a second guide bar 62, a plurality of support bars 70, and the static eliminator 450.

The carrier 600 transported in a horizontal position through the transport unit 31 may be loaded into the peeling device 2000. Here, the substrate tray 700 accommodated in the carrier 600 in the horizontal position may further include a plurality of first clamps 11 and a plurality of first holes 41 disposed at an edge of the support plate 710 and a plurality of second clamps 12 and a plurality of second holes 42 disposed at the other edge of the support plate 710 as illustrated in FIG. 5. The first clamps 11 and the first holes 41 may be disposed adjacent to the first bar 601 of the carrier 600. The second clamps 12 and the second holes 42 may be disposed adjacent to the second bar 602 of the carrier 600. The first clamps 11 and the first holes 41 may be disposed alternately along the second direction DR2. The second clamps 12 and the second holes 42 may be disposed alternately along the second direction DR2. The first clamps 11, the first holes 41, the second clamps 12, and the second holes 42 may be exposed to the outside through through-holes penetrating the electrostatic chuck 720. The first clamps 11 and the second clamps 12 may face each other, respectively, and the first holes 41 and the second holes 42 may face each other, respectively. The first holes 41 and the second holes 42 may be disposed to correspond to grippers 84 which will be described later.

The transport unit 31 may be disposed along the first direction DR1. The transport unit 31 may transport the carrier 600 along the first direction DR1. The transport unit 31 may include pairs of rollers 32 and a connecting shaft 33 connecting each pair of the rollers 32. The connecting shaft 33 may extend along the second direction DR2. Each pair of the rollers 32 may be connected to a side and the other side of the connecting shaft 33, respectively. Each pair of the rollers 32 may be rotatably connected to the connecting shaft 33, respectively.

The first guide bar 61 and the second guide bar 62 may face each other. For example, the first guide bar 61 and the second guide bar 62 may face each other in the second direction DR2.

The first guide bar 61 may include a first rail 61a and a first opening 61b. The first rail 61a may be disposed on the first guide bar 61 along an extending direction (or a longitudinal direction; e.g., the first direction DR1) of the first guide bar 61. The first opening 61b may penetrate the first guide bar 61. The first opening 61b may extend along the first rail 61a. The substrate 50 may be loaded into the peeling device 2000 from the outside through the first opening 61b or may be unloaded from the peeling device 2000 to the outside through the first opening 61b.

The second guide bar 62 may include a second rail 62a and a second opening 62b. The second rail 62a may be disposed on the second guide bar 62 along an extending direction (or a longitudinal direction; e.g., the first direction DR1) of the second guide bar 62. The second opening 62b may penetrate the second guide bar 62. The second opening 62b may extend along the second rail 62a. The substrate 50 may be loaded into the peeling device 2000 from the outside through the second opening 62b or may be unloaded from the peeling device 2000 to the outside through the second opening 62b.

The support bars 70 may be disposed between the first guide bar 61 and the second guide bar 62. FIG. 5 illustrates an example in which two support bars 70 are spaced apart from each other in the first direction DR1. Each of the support bars 70 may be disposed parallel to the connecting shaft 33 of the transport unit 31. The support bars 70 may extend in the second direction DR2. The support bars 70 may connect the first guide bar 61 and the second guide bar 62 to each other. For example, an end of each of the support bars 70 may be connected to an inner surface of the first guide bar 61, and the other end of each of the support bars 70 may be connected to an inner surface of the second guide bar 62.

The peeling stage 40 may be disposed on the support bars 70. For example, the peeling stage 40 may be disposed on the support bars 70 between the first guide bar 61 and the second guide bar 62. The peeling stage 40 may be connected to the support bars 70. The peeling stage 40 may include a base plate 411 and a plurality of support pins 422.

The base plate 411 of the peeling stage 40 may be disposed on the support bars 70. The base plate 411 may be connected to the support bars 70. The support pins 422 of the peeling stage 40 may be disposed on the base plate 411. The support pins 422 may be shaped like pillars protruding upward from the base plate 411. The support pins 422 may be coupled to the base plate 411. For example, an end of each support pin 422 may be coupled to the base plate 411. A spherical ball rotatably connected to each support pin 422 may be disposed at the other end of the support pin 422. The support pins 422 may be arranged in a matrix form on the base plate 411.

The movable object 80 may be disposed on the peeling stage 40. For example, the movable object 80 may be disposed on the peeling stage 40 to overlap the peeling stage 40. The movable object 80 may be movably coupled to the first guide bar 61 and the second guide bar 62. The movable object 80 may be disposed between the first guide bar 61 and the second guide bar 62 and may move along the first rail 61a of the first guide bar 61 and the second rail 62a of the second guide bar 62. For example, the movable object 80 may move on the peeling stage 40 along the first direction DR1 or the first reverse direction while being guided by the first rail 61a and the second rail 62a. The movable object 80 may include the support 83, a first driver 85, a second driver 86, a first coupling portion 81, a second coupling portion 82, and the grippers 84.

The support 83 of the movable object 80 may be disposed between the first guide bar 61 and the second guide bar 62. The support 83 may extend along the second direction DR2. The support 83 may be disposed on the peeling stage 40 to overlap the peeling stage 40. The support 83 may have an “r”-shaped cross section.

According to an embodiment, as illustrated in FIG. 6, the support 83 may include a horizontal portion 83a and a vertical portion 83b. The vertical portion 83b may extend downward from a side of the horizontal portion 83a. For example, the vertical portion 83b may extend from a side of the horizontal portion 83a along the third reverse direction.

The grippers 84 of the movable object 80 may be disposed on the support 83. The grippers 84 may be disposed on a lower side of the support 83. The grippers 84 may be arranged in a row along the support 83 in the second direction DR2 between the first guide bar 61 and the second guide bar 62. In other words, the grippers 84 may be disposed under the support 83 along the extending direction (e.g., the second direction DR2) of the support 83. The grippers 84 may be coupled to and supported by the support 83. The grippers 84 may have an “L” shaped cross section.

According to an embodiment, as illustrated in FIG. 6, a gripper 84 may include a coupling portion 84a, a first extension portion 84c, a second extension portion 84b, and a pressing portion 84d.

The coupling portion 84a of the gripper 84 may be connected to the vertical portion 83b of the support 83.

The first extension portion 84c of the gripper 84 may extend along the first reverse direction from an edge of the coupling portion 84a.

The second extension portion 84b of the gripper 84 may be disposed on the first extension portion 84c. For example, the second extension portion 84b may be disposed between the first extension portion 84c and the support 83. The second extension portion 84b may extend along the first reverse direction from a middle portion of the coupling portion 84a.

The pressing portion 84d of the gripper 84 may be disposed between the first extension portion 84c and the second extension portion 84b. The pressing portion 84d may be movably connected to the second extension portion 84b. For example, the pressing portion 84d may move between the first extension portion 84c and the second extension portion 84b toward the first extension portion 84c or toward the second extension portion 84b. The pressing portion 84d may be, for example, connected to an actuator disposed in the second extension portion 84b.

The gripper 84 may grip the substrate 50 through the pressing portion 84d and the first extension portion 84c. For example, when the pressing portion 84d moves toward the first extension portion 84c, the substrate 50 may contact the first extension portion 84c and the pressing portion 84d. Here, the substrate 50 may be supported between the first extension portion 84c and the pressing portion 84d by the pressure applied by the pressing portion 84d.

The gripper 84 may also include only the coupling portion 84a and the first extension portion 84c described above. In other words, the second extension portion 84b and the pressing portion 84d can be omitted from the gripper 84 of FIG. 6.

The first coupling portion 81 of the movable object 80 may be movably coupled to the first rail 61a of the first guide bar 61. The first coupling portion 81 may include a first wheel (not shown) movably coupled to the first rail 61a. Therefore, the first coupling portion 81 may be moved along the first rail 61a by driving the first wheel.

The second coupling portion 82 of the movable object 80 may be movably coupled to the second rail 62a of the second guide bar 62. The second coupling portion 82 may include a second wheel (not shown) movably coupled to the second rail 62a. Therefore, the second coupling portion 82 may be moved along the second rail 62a by driving the second wheel. A center of a rotation axis of the first wheel and a center of a rotation axis of the second wheel may be parallel to each other and may also coincide with each other. A rotation direction of the first wheel and a rotation direction of the second wheel may be the same.

The first driver 85 of the movable object 80 may be disposed on the support 83 on a side of the support 83. The first driver 85 may be connected to a side of the support 83 and a side of the first coupling portion 81. For example, the first driver 85 may include a first actuator 971 connected to a side of the support 83. The first actuator 971 may be extended (or expanded) and retracted under the control of the first driver 85. The first driver 85 may include a first rotating shaft 981 rotatably connected to a side of the first coupling portion 81. The first driver 85 may be rotated clockwise or counterclockwise by the first rotating shaft 981. The first driver 85 may control the rotation direction of the first wheel of the first coupling portion 81.

The second driver 86 of the movable object 80 may be disposed on the support 83 on the other side of the support 83. The second driver 86 may be connected to the other side of the support 83 and a side of the second coupling portion 82. For example, the second driver 86 may include a second actuator 972 connected to the other side of the support 83. The second actuator 972 may be extended and retracted under the control of the second driver 86. The second driver 86 may include a second rotating shaft 982 rotatably connected to a side of the second coupling portion 82. The second driver 86 may be rotated clockwise or counterclockwise by the second rotating shaft 982. A center of the second rotating shaft 982 and a center of the first rotating shaft 981 may be parallel to each other and may also coincide with each other. The second driver 86 may control the rotation direction of the second wheel of the second coupling portion 82.

The support 83 may be moved in a direction away from the first driver 85 and the second driver 86 or may be moved in a direction approaching the first driver 85 and the second driver 86 by the operation of the first actuator 971 of the first driver 85 and the second actuator 972 of the second driver 86. For example, when the first actuator 971 and the second actuator 972 operate in a direction in which they are extended, the support 83 may move in the direction away from the first driver 85 and the second driver 86. On the other hand, when the first actuator 971 and the second actuator 972 operate in a direction in which they are retracted, the support 83 may move in the direction approaching the first driver 85 and the second driver 86. Accordingly, a distance between the support 83 and the peeling stage 40 can be adjusted.

The support 83 may be rotated clockwise or counterclockwise about the first rotating shaft 981 (or the second rotating shaft 982) by the operation of the first rotating shaft 981 of the first driver 85 and the second rotating shaft 982 of the second driver 86. Accordingly, the support 83 may be rotated clockwise or counterclockwise about the first rotating shaft 981 of the first driver 85 (or the second rotating shaft 982 of the second driver 86).

The first driving arm 95 may control a tilt angle of the first guide bar 61. The first driving arm 95 may be rotatably connected to the other side of the first coupling portion 81. The first driving arm 95 may include a first link 91 and a second link 92. A side of the first link 91 may be rotatably connected to the first coupling portion 81. For example, a side of the first link 91 may be connected to the first rotating shaft 981 of the first driver 85. The other side of the first link 91 may be rotatably connected to the second link 92. A side of the second link 92 may be connected to a first driving motor (not shown).

Although not illustrated, a second driving arm may be further connected to the other side (e.g., side in the second direction DR2) of the second coupling portion 82 to control a tilt angle of the second guide bar 62. The second driving arm may face the first driving arm 95 described above and may have substantially the same configuration as the first driving arm 95. For example, the second driving arm may be rotatably connected to the second coupling portion 82. The second driving arm may include a third link corresponding to the first link 91 and a fourth link corresponding to the second link 92. A side of the third link may be rotatably connected to the second coupling portion 82. For example, a side of the third link may be connected to the second rotating shaft 982 of the second driver 86. The other side of the third link may be rotatably connected to the fourth link. A side of the fourth link may be connected to a second driving motor.

The tilt angles of the first guide bar 61 and the second guide bar 62 may be controlled by driving the links of the first driving arm 95 (e.g., the first link 91 and the second link 92) and the links of the second driving arm (e.g., the third link and the fourth link). Accordingly, tilt angles of the support bars 70 connected to the guide bars 61 and 62 may be controlled. In addition, as the tilt angles of the support bars 70 are controlled, a tilt angle of the peeling stage 40 connected to the support bars 70 may be controlled. Consequently, the tiltangle of the peeling stage 40 may be controlled by driving the links of the first driving arm 95 (e.g., the first link 91 and the second link 92) and the links of the second driving arm (e.g., the third link and the fourth link).

The static eliminator 450 (e.g., an ionizer) may provide ions for removing static electricity. The static eliminator 450 may include an ion generator 451 and a plurality of nozzles 452 as illustrated in FIG. 7. Since the substrate 50 may be attached onto the electrostatic chuck 720 of the substrate tray 700 by an electrostatic force, the static eliminator 450 may provide ions to an interface between the substrate 50 and the electrostatic chuck 720. Accordingly, the substrate 50 can be easily separated (or peeled) from the electrostatic chuck 720.

The ion generator 451 may generate ions. For example, the ion generator 451 may generate ions by ionizing inside air using a corona discharge method, a radiation irradiation method, or an ultraviolet irradiation method.

The nozzles 452 may be connected to the ion generator 451. The nozzles 452 may emit ions generated by the ion generator 451 to the outside. For example, ions from the ion generator 451 may be sprayed to the outside through the nozzles 452 together with air accelerated at high pressure.

According to an embodiment, the ion generator 451 of the static eliminator 450 may be disposed, for example, inside the peeling stage 40. However, the present disclosure is not limited thereto, and the ion generator 451 may also be disposed outside the peeling stage 40.

According to an embodiment, the nozzles 452 of the static eliminator 450 may be disposed, for example, on a side of the peeling stage 40. For example, a transport direction (e.g., the first direction DR1) of the transport unit 31 with respect to the peeling stage 40 may be defined as a “downstream direction”, and an opposite direction (or a reverse direction) of the transport direction of the transport unit 31 may be defined as an “upstream direction”. In this case, the nozzles 452 may be disposed at an end of the peeling stage 40 which faces the upstream direction. In other words, the nozzles 452 may be disposed at an edge (or a side) of the peeling stage 40 in the upstream direction (i.e., left side in FIG. 7). The nozzles 452 may be arranged at the side of the peeling stage 40 along a longitudinal direction of the side. For example, the nozzles 452 may be arranged at the end of the peeling stage 40 at regular intervals along the second direction DR2. The nozzles 452 may spray ions in the upstream direction (e.g., direction opposite to the first direction DR1). For example, the nozzles 452 may spray ions in the first reverse direction from the end of the peeling stage 40.

The operation of the peeling device 2000 for a display device according to the embodiment will be described in detail as follows.

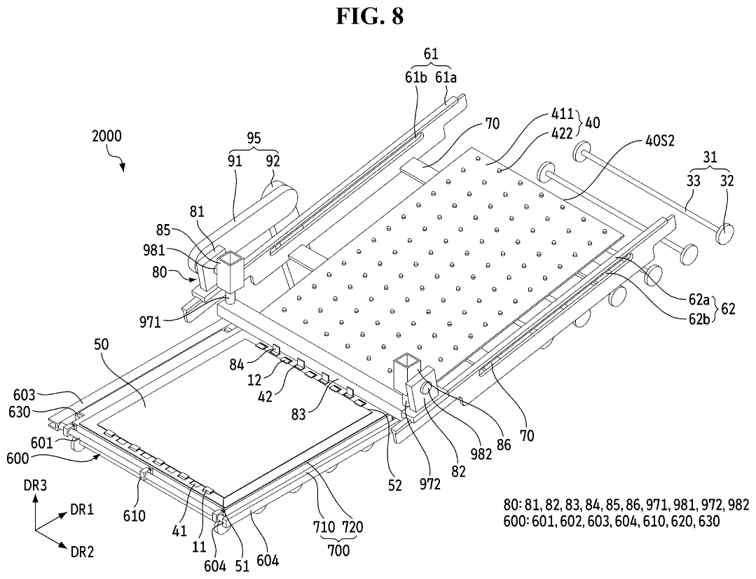

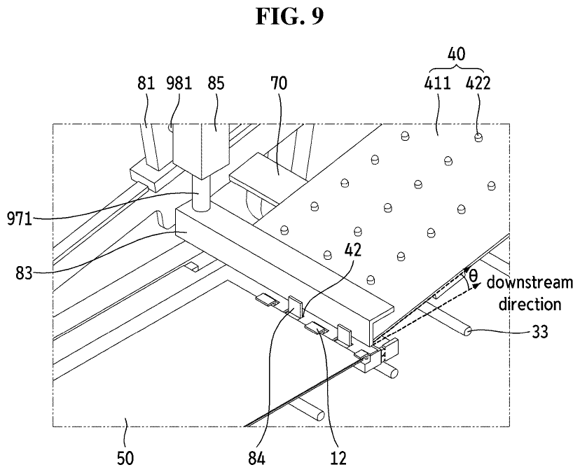

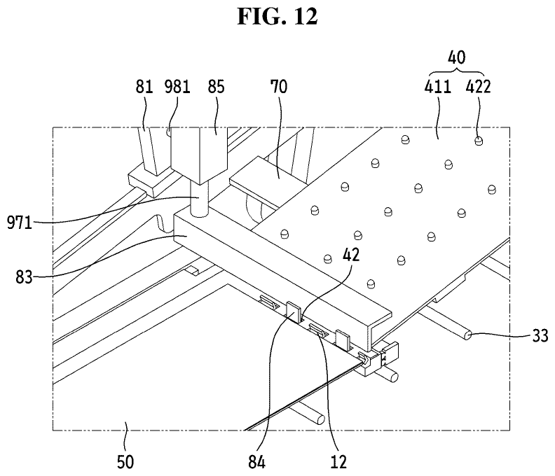

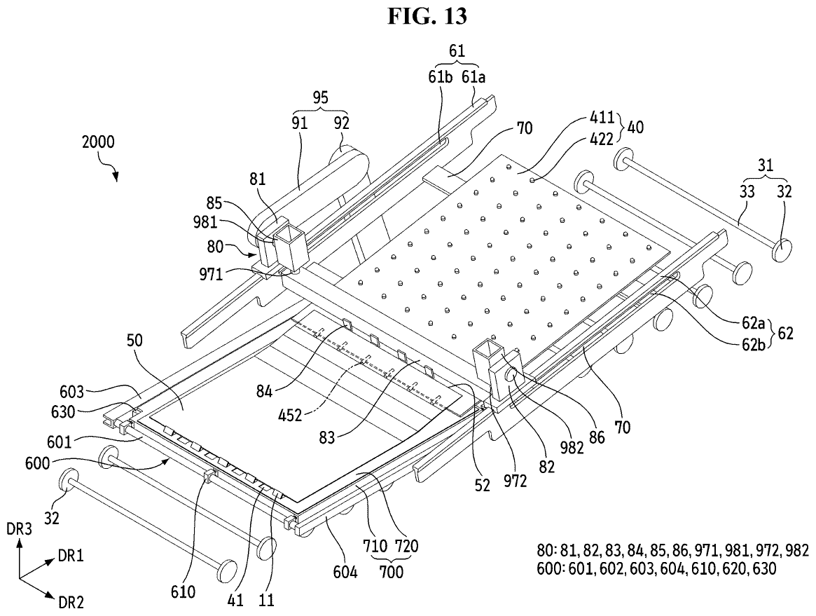

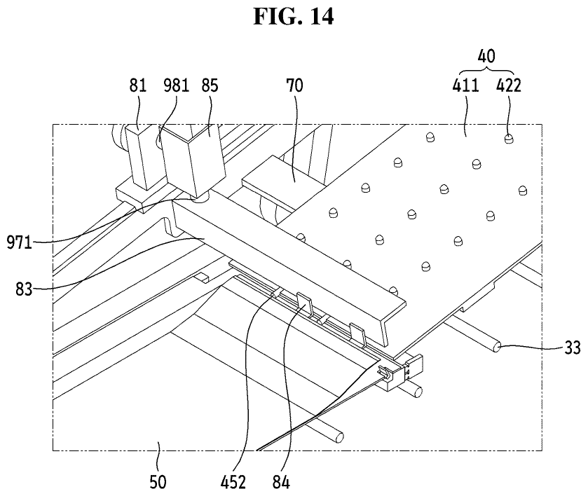

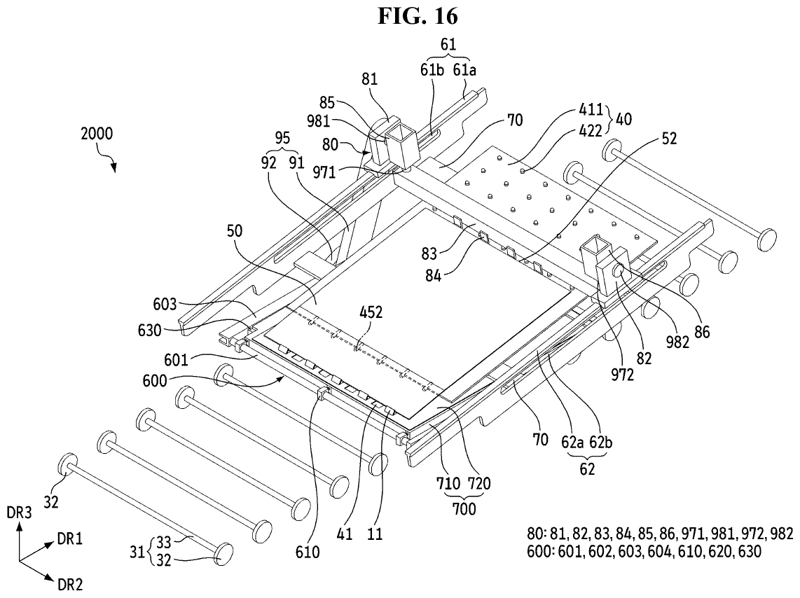

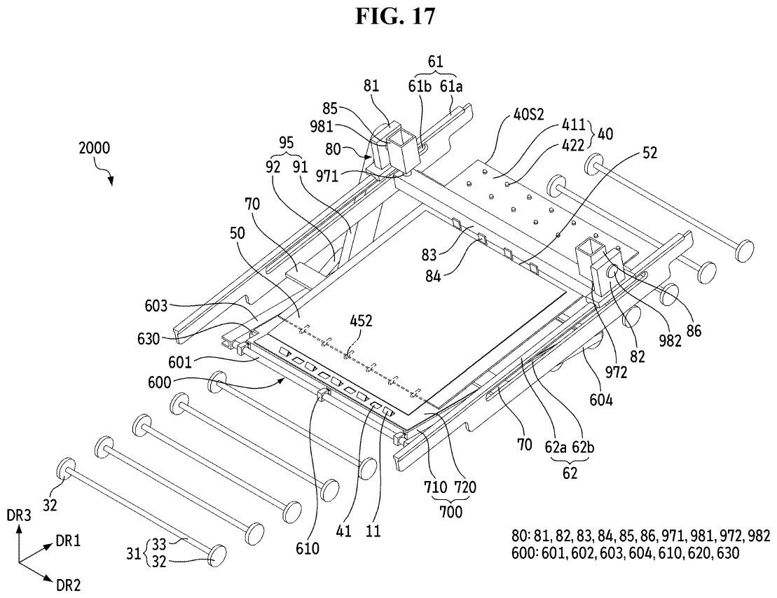

FIGS. 8, 9, 10, 11, 12, 13, 14, 15, 16, 17, 18, 19, 20 and 21 are views for explaining a peeling method using a peeling device for a display device according to an embodiment. Here, FIG. 9 is an enlarged view of an area around the second clamps 12 and the second holes 42 of FIG. 8. FIG. 12 is an enlarged view of the area around the second clamps 12 and the second holes 42 of FIG. 11. FIG. 14 is an enlarged view of the area around the second clamps 12 and the second holes 42 of FIG. 13.

First, as illustrated in FIGS. 8 and 9, the carrier 600 (e.g., the carrier 600 in which the substrate tray 700 is accommodated) may be placed on the transport unit 31 of the peeling device 2000. The substrate 50 may be placed on the electrostatic chuck 720 of the substrate tray 700 accommodated in the carrier 600. Here, a first side 51 of the substrate 50 may be supported by the first clamps 11. For example, the first side 51 of the substrate 50 in the upstream direction may be clamped (or gripped) by the first clamps 11. On the other hand, a second side 52 of the substrate 50 in the downstream direction may be supported by the second clamps 12. For example, the second side 52 of the substrate 50 in the downstream direction may be clamped (or gripped) by the second clamps 12. Here, a portion of the first side 51 of the substrate 50 may overlap the first holes 41. The portion of the first side 51 which overlaps the first holes 41 may not contact the electrostatic chuck 720. A portion of the second side 52 of the substrate 50 may overlap the second holes 42. The portion of the second side 52 which overlaps the second holes 42 may not contact the electrostatic chuck 720.

In addition, as illustrated in FIGS. 8 and 9, the peeling stage 40 may be placed adjacent to the carrier 600 in the downstream direction of the carrier 600. At this time, the peeling stage 40 may be tilted (rotated) toward the carrier 600. For example, the peeling stage 40 may be tilted in the upstream direction as the first guide bar 61 and the second guide bar 62 are tilted under the control of the first driving arm 95 and the second driving arm. Specifically, the peeling stage 40 may be tilted at a predetermined angle θ so that an upper surface of the peeling stage 40 (e.g., a surface on which the support pins 422 are disposed) faces the upstream direction of the transport unit 31 and that a lower surface of the peeling stage 40 (e.g., a surface opposite the upper surface of the peeling stage 40) faces the downstream direction of the transport unit 31. In other words, the peeling stage 40 may be rotated at the predetermined angle θ with respect to a first side 40S1 of the peeling stage 40 facing the carrier 600 so that a second side 40S2 of the peeling stage 40 opposite to the first side is lifted in the upward direction (i.e., third direction DR3). Here, the rotation direction of the peeling stage 40, which makes the second side lifted in the upward direction, is referred to as a “first rotation direction”, and a second rotation direction is defined as a direction opposite to the first rotation direction. Here, an angle (180-0 degrees) formed by the upper surface of the tilted peeling stage 40 and the transport unit 31 in the upstream direction may be an obtuse angle. In addition, an angle θ formed by the lower surface of the tilted peeling stage 40 and the transport unit 31 in the downstream direction may be an acute angle. Here, an edge (i.e., the first side) of the peeling stage 40 may be placed on an edge of the substrate tray 700 so that the edge of the tilted peeling stage 40 overlaps the edge of the substrate tray 700.

In addition, as illustrated in FIGS. 8 and 9, the movable object 80 may be placed between the carrier 600 and the peeling stage 40 to overlap edges of the carrier 600 and the peeling stage 40 which are adjacent to each other.

In addition, as illustrated in FIGS. 8 and 9, the grippers 84 may be inserted into the second holes 42, respectively. For example, the grippers 84 may be inserted into the second holes 42, respectively, such that grippers 84 are located more toward the downstream direction in respective spaces of the second holes 42. Here, since a size of each second hole 42 in the first direction DR1 is larger than a size of each gripper 84 in the first direction DR1, when the grippers 84 are inserted into the second holes 42, respectively, there may be a free space (or gap) in each second hole 42. For example, when the grippers 84 are inserted into the second holes 42, there may be a free space in each second hole 42 so that the grippers 84 can move further in the upstream direction. Here, the grippers 84 inserted into the second holes 42, respectively, do not contact the substrate 50.

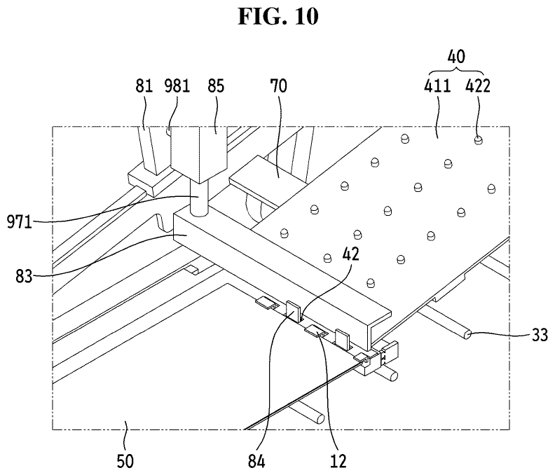

Next, as illustrated in FIG. 10, the support 83 may move a predetermined distance in the upstream direction along the first guide bar 61 and the second guide bar 62. Accordingly, the grippers 84 connected to the support 83 may be moved in the upstream direction. Then, the grippers 84 may be moved within the free spaces of the second holes 42. Therefore, the grippers 84 and the substrate 50 may overlap each other. For example, the grippers 84 and the second side 52 of the substrate 50 may overlap in the third direction DR3.

Next, as illustrated in FIG. 11, the first clamps 11 may be opened. For example, a constraining force of the first clamps 11 applied to the first side 51 of the substrate 50 may be released by rotating the first clamps 11 to the upward direction (i.e., the third direction DR3). In addition, as illustrated in FIGS. 11 and 12, the second clamps 12 may be opened. For example, a constraining force of the second clamps 12 applied to the second side 52 of the substrate 50 may be released by rotating the second clamps 12 to the upward direction. Accordingly, the substrate 50 may not be supported by the first clamps 11 and the second clamps 12.

Next, as illustrated in FIGS. 13 and 14, the support 83 may be raised away from the substrate 50 by the first driver 85 and the second driver 86. Accordingly, the grippers 84 connected to the support 83 may come out of the second holes 42 and ascend to contact a lower surface of the substrate 50. Therefore, the second side 52 of the substrate 50 may be lifted while being supported by the grippers 84. Next, the support 83 may move a predetermined distance in a direction to the second side 40S2 of the peeling stage 40 and rotate at a predetermined angle (i.e., the angle θ) in the first rotation direction so that the support 83 may be parallel to a major surface of the peeling stage 40. Accordingly, the grippers 84 may move the predetermined distance in the direction to the second side 40S2 of the peeling stage 40 and rotate at the predetermined angle in the first rotation direction. Then, the second side 52 of the substrate 50 and its surroundings may be lifted while being separated from the electrostatic chuck 720. Accordingly, the interface between the substrate 50 and the electrostatic chuck 720 may be exposed, and the nozzles 452 of the static eliminator 450 may face the interface. Before the second side 52 of the substrate 50 is lifted, the electrostatic force of the electrostatic chuck 720 may be released. For example, before second side 52 of the substrate 50 is lifted, the supply of power to the electrostatic chuck 720 may be cut off, thereby removing the electrostatic force provided from the electrostatic chuck 720 to the substrate 50. Even if the supply of the electrostatic force from the electrostatic chuck 720 is cut off, the substrate 50 may be kept attached to the electrostatic chuck 720 by the static electricity that remains without being discharged.

Next, the static eliminator 450 may spray ions to the interface between the substrate 50 and the electrostatic chuck 720. The static electricity between the substrate 50 and the electrostatic chuck 720 may be removed (or neutralized) by the ions from the static eliminator 450. Therefore, a bonding force between the substrate 50 and the electrostatic chuck 720 may be weakened. As a result, the substrate 50 can be easily separated from the electrostatic chuck 720.

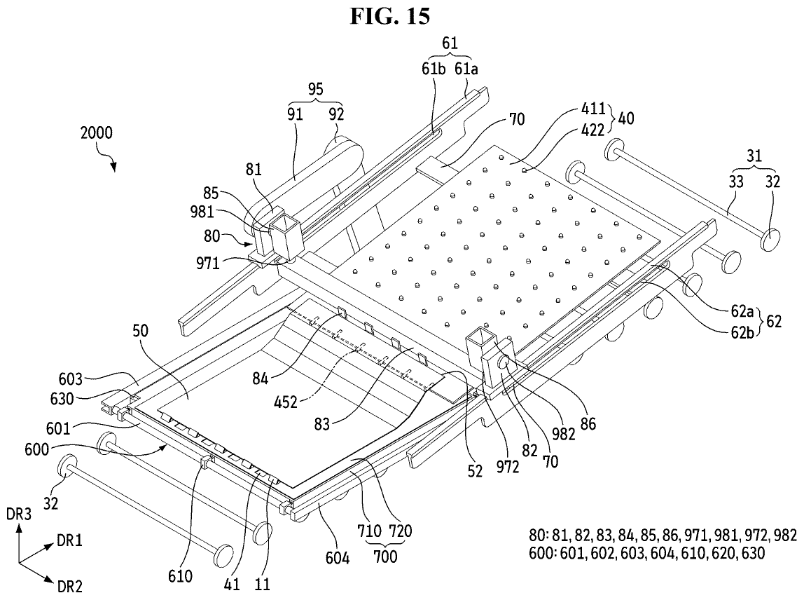

Next, as illustrated in FIGS. 15 through 18, the carrier 600 and the support 83 may move in the direction to the second side 40S2. For example, the carrier 600 may move in the downstream direction along the transport unit 31, and the support 83 may move in the downstream direction on the peeling stage 40 (e.g., the tilted peeling stage 40) along the first guide bar 61 and the second guide bar 62. Therefore, the substrate 50 may be lifted from the electrostatic chuck 720 to the peeling stage 40 while being supported by the grippers 84 connected to the support 83.

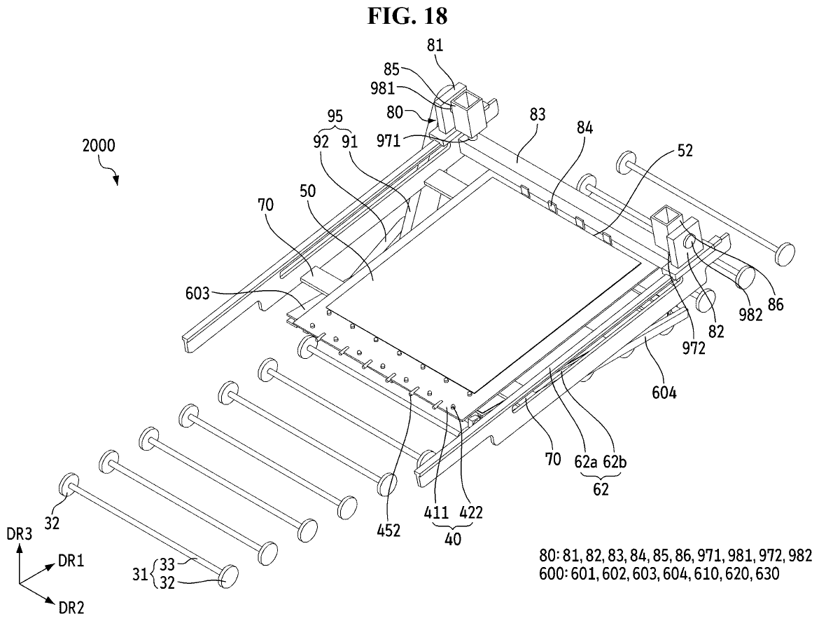

As described above, while the support 83 is moved in the direction to the second side 40S2 on the peeling stage 40 along the tilted first and second guide bars 61 and 62, the carrier 600 is moved in the downstream stream along the horizontal transport unit 31 which is not tilted. Therefore, when the support 83 and the carrier 600 are moved together along different directions, the substrate 50 may be apart from the electrostatic chuck 720 to the peeling stage 40 while being changed from a horizontal position to a tilted position. For example, as illustrated in FIG. 18, when the peeling stage 40 and the carrier 600 are completely (or almost completely) separated from each other, the substrate 50 may be placed on the support pins 422 of the peeling stage 40 while the carrier 600 may be placed under the peeling stage 40. In other words, as illustrated in FIG. 18, when the peeling stage 40 and the carrier 600 are completely (or almost completely) separated from each other, the substrate 50 may be transferred from the electrostatic chuck 720 to the peeling stage 40.

As illustrated in FIGS. 15 through 17, as the carrier 600 (or the substrate tray 700 on the carrier 600) and the support 83 are moved together in the different directions, a contact area between the peeling stage 40 (e.g., the support pins 422 of the peeling stage 40) and the substrate 50 may gradually increase, but a contact area between the electrostatic chuck 720 of the substrate tray 700 accommodated in the carrier 600 and the substrate 50 may gradually decrease.

According to an embodiment, since the static eliminator 450 continuously provides ions between (or to an interface between) the substrate 50 and the electrostatic chuck 720 during the processes from FIG. 14 to FIG. 18, the substrate 50 can be easily separated (or peeled) from the electrostatic chuck 720. In other words, from the time when the second side 52 of the substrate 50 is lifted, the static eliminator 450 may continuously provide ions between (or to the interface between) the substrate 50 and the electrostatic chuck 720 while the substrate 50 is moved from the electrostatic chuck 720 to the peeling stage 40.

In addition, according to an embodiment, the nozzles 452 of the static eliminator 450 are disposed at an edge (i.e., the first side 40S1) of the peeling stage 40 to face the interface between the substrate 50 and the electrostatic chuck 720. Therefore, ions from the nozzles 452 can be more directly and quickly provided to the interface between the substrate 50 and the electrostatic chuck 720 during a peeling process. Accordingly, the substrate 50 can be more easily separated from the electrostatic chuck 720 during the peeling process. Therefore, tact time of the peeling process can be reduced, thereby improving productivity.

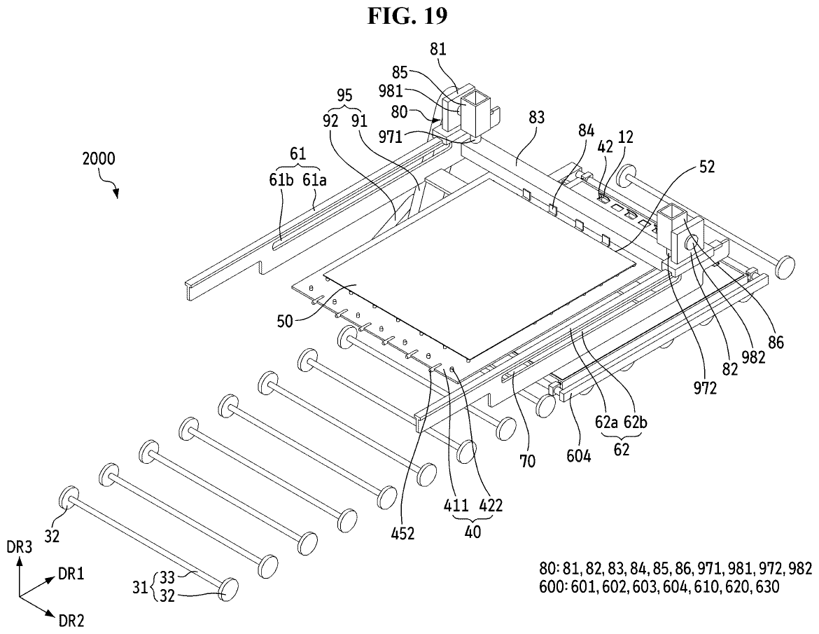

Next, as illustrated in FIG. 19, the peeling stage 40 may be rotated to have a horizontal position while the second side 52 of the substrate 50 is supported by the grippers 84. For example, while the second side 52 of the substrate 50 is supported by the grippers 84, the peeling stage 40 may be tilted in the second rotation direction. As an example, the peeling stage 40 may be placed parallel to the transport unit 31 as the first guide bar 61 and the second guide bar 62 are tilted under the control of the first driving arm 95 and the second driving arm. Accordingly, the substrate 50 on the peeling stage 40 may also have a horizontal position parallel to the transport unit 31.

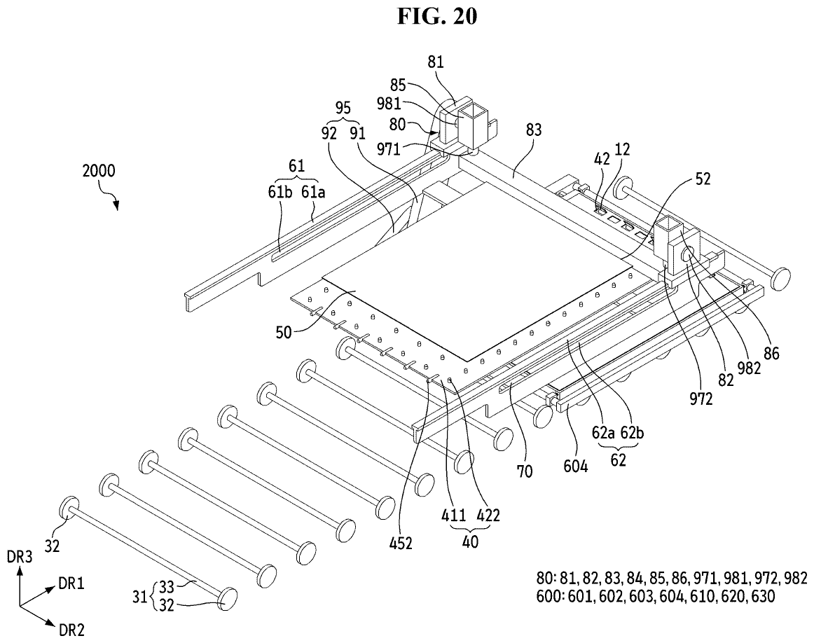

Next, as illustrated in FIG. 20, as the support 83 is lowered by a predetermined distance toward the peeling stage 40 along the third reverse direction, the second side 52 of the substrate 50 and the grippers 84 may be separated. Next, the substrate 50 on the peeling stage 40 may be lifted from the support pins 422 of the peeling stage 40 by a robot arm (not shown). As a specific example, the robot arm may include a plurality of fingers spaced apart from each other. The fingers of the robot arm may be placed between the substrate 50 and the peeling stage 40 through the first opening 61b of the first guide bar 61 in a horizontal position. Here, the fingers may be placed between the support pins 422. When the fingers placed between the substrate 50 and the peeling stage 40 are raised toward the substrate 50 along the third direction DR3, the substrate 50 may be raised in the third direction DR3 while being supported by the fingers. Accordingly, the substrate 50 may be moved from the support pins 422 to the fingers.

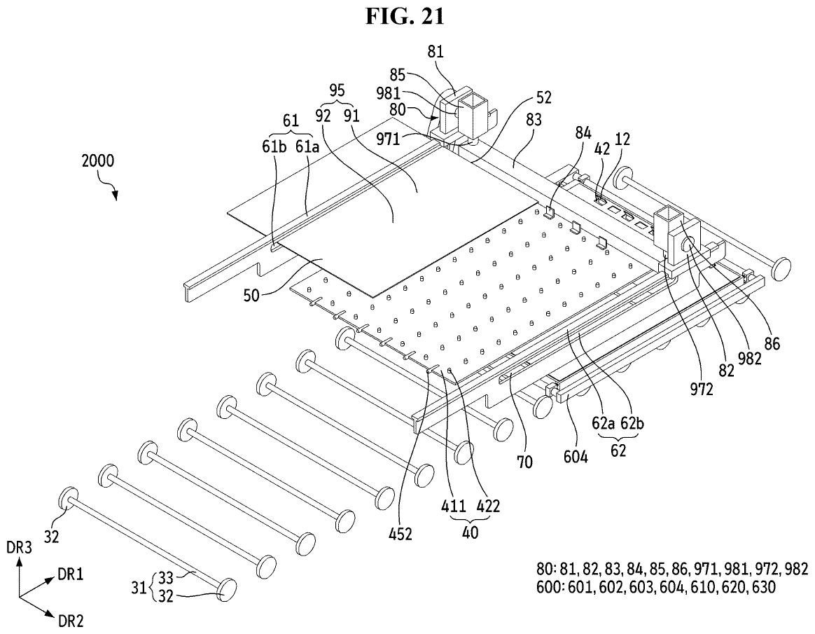

Next, as illustrated in FIG. 21, the fingers on which the substrate 50 is placed may be taken out through the first opening 61b of the first guide bar 61. Accordingly, the substrate 50 may be unloaded from the peeling device 2000.

According to a peeling device peeling method for display device according to an embodiment, a substrate can be easily separated from an electrostatic chuck through a static eliminator.

The display device according to the embodiment can be applied to various electronic devices. The electronic device according to one embodiment includes the display device described above and may further include modules or devices having additional functions in addition to the display device.

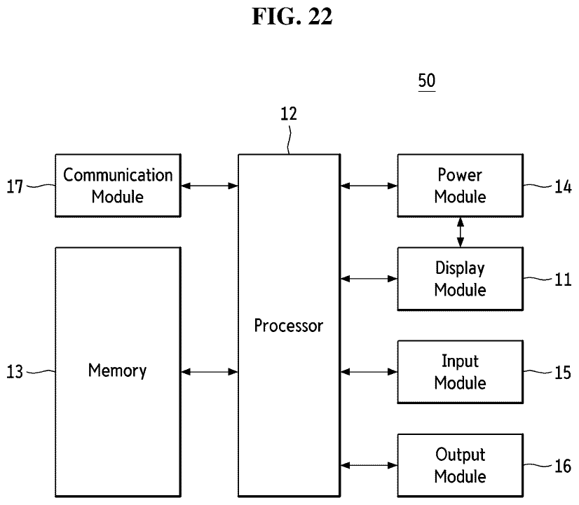

FIG. 22 is a block diagram of an electronic device according to one embodiment. Referring to FIG. 22, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

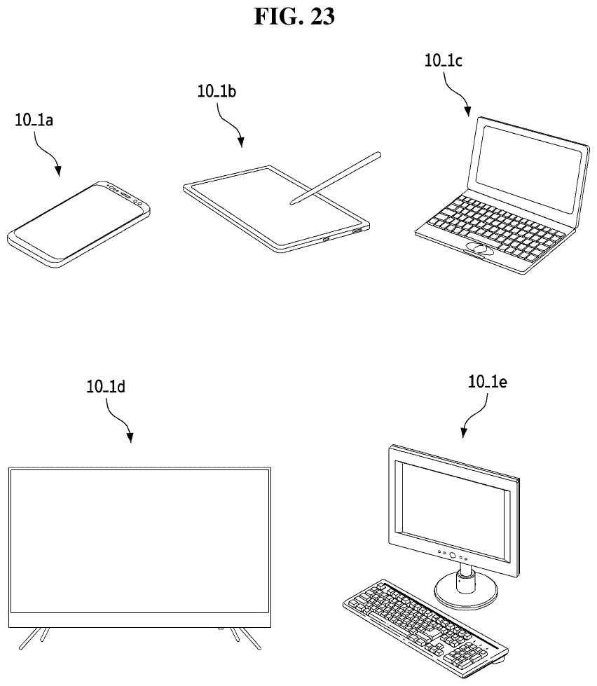

FIGS. 23, 24, and 25 are schematic diagrams of electronic devices according to various embodiments. FIGS. 23 to 25 illustrate examples of various electronic devices to which the display device according to the embodiments is applied.

FIG. 23 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

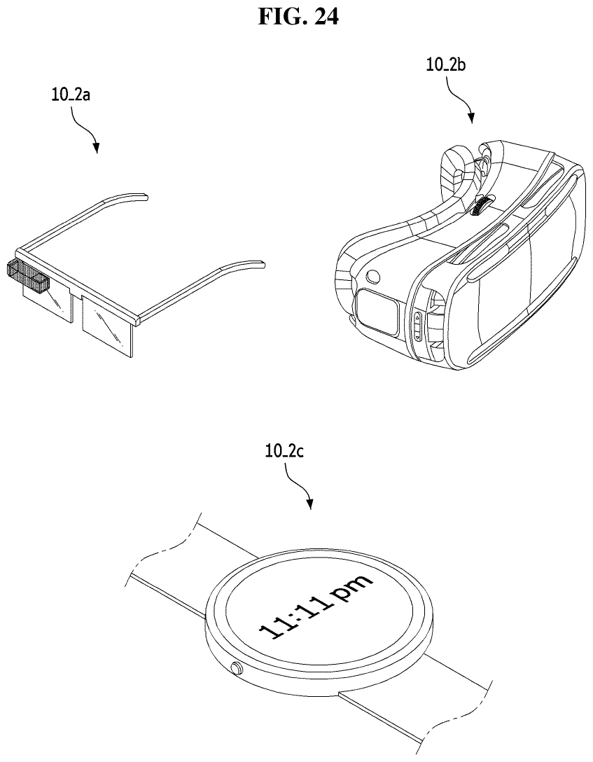

FIG. 24 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

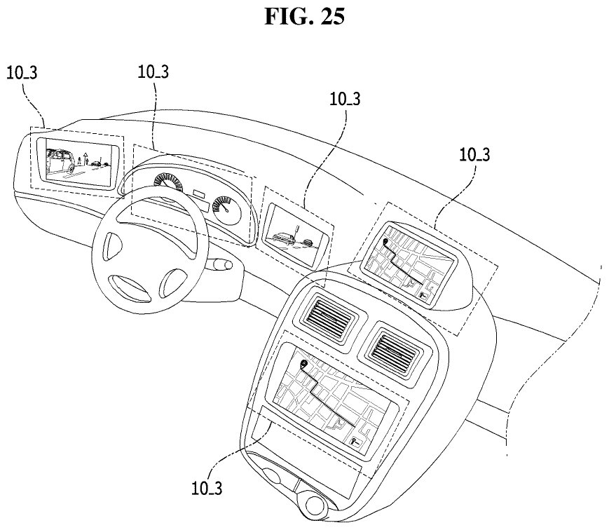

The smart watch 10_2c includes a biometric sensor as an input device, and may provide biometric information recognized by the biometric sensor to the user through the display module. FIG. 25 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that the exemplary embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A peeling device for a display device, the peeling device comprising:
a transport unit;
a carrier movable on and along the transport unit and having a substrate tray accommodated therein;
a rotatable peeling stage disposed on the transport unit;
a support disposed on the peeling stage and movable on the peeling stage along an upstream direction of the transport unit, a downstream direction of the transport unit, a downward direction toward the peeling stage, and an upward direction opposite to the downward direction, and rotatable in a first rotation direction, and a second rotation direction opposite to the first rotation direction;
a gripper connected to the support so as to be disposed between the support and the peeling stage; and
a static eliminator disposed on a side of the peeling stage.

2. The peeling device of claim 1, wherein the static eliminator comprises:
an ion generator disposed inside the peeling stage; and
a nozzle disposed at an edge of the peeling stage and connected to the ion generator.

3. The peeling device of claim 2, wherein the edge of the peeling stage is disposed in the upstream direction from a center of the peeling stage.

4. The peeling device of claim 2, wherein the nozzle comprises a plurality of nozzles connected to the ion generator, and the nozzles are disposed along the edge of the peeling stage.

5. The peeling device of claim 1, wherein the peeling stage comprises:
a base plate on the transport unit; and
a support pin on the base plate.

6. The peeling device of claim 1, further comprising:
a first driver connected to one end of the support; and
a second driver connected to an opposite end of the support.

7. The peeling device of claim 6, wherein the first driver comprises a first actuator connected to the one end of the support, and the second driver comprises a second actuator connected to the opposite end of the support.

8. The peeling device of claim 6, further comprising:
a first guide bar disposed on the one end of the support; and
a second guide bar disposed on the opposite end of the support.

9. The peeling device of claim 8, further comprising:
a first coupling portion connected to the first guide bar so as to be movable along the first guide bar; and
a second coupling portion connected to the second guide bar so as to be movable along the second guide bar.

10. The peeling device of claim 9, wherein the first driver is rotatably coupled to the first coupling portion, and the second driver is rotatably coupled to the second coupling portion.

11. The peeling device of claim 10, further comprising:
a first driving arm rotatably connected to the first coupling portion; and
a second driving arm rotatably connected to the second coupling portion.

12. The peeling device of claim 9, wherein the first guide bar comprises:
a first rail connected to the first coupling portion; and
a first opening extending along the first rail.

13. The peeling device of claim 12, wherein the second guide bar comprises:
a second rail connected to the second coupling portion; and
a second opening extending along the second rail.

14. The peeling device of claim 8, further comprising a support bar disposed between the first guide bar and the second guide bar and between the transport unit and the peeling stage.

15. The peeling device of claim 14, wherein the support bar is connected to the first guide bar, the second guide bar, and the peeling stage.

16. The peeling device of claim 1, wherein the substrate tray comprises an electrostatic chuck, a first clamp disposed at one side portion of the electrostatic chuck, a first hole defined adjacent to the first clamp, a second clamp disposed at an opposite side portion of the electrostatic chuck and a second hole defined adjacent to the second clamp, and
the gripper is disposed in the second hole of the substrate tray.

17. The peeling device of claim 1, wherein the peeling stage is rotatable at a predetermined angle with respect to a first side of the peeling stage facing the carrier in the first rotation direction so that a second side of the peeling stage opposite to the first side is lifted in the upward direction.

18. A peeling method for a display device, the peeling method comprising:
preparing a peeling device for a display device, wherein the peeling device comprises a transport unit, a carrier movable on and along the transport unit and having a substrate tray accommodated therein, a rotatable peeling stage disposed on the transport unit, a support disposed on the peeling stage and movable on the peeling stage along an upstream direction of the transport unit, a downstream direction of the transport unit, a downward direction toward the peeling stage, and an upward direction opposite to the downward direction, and rotatable in a first rotation direction, and a second rotation direction opposite to the first rotation direction, a gripper connected to the support so as to be disposed between the support and the peeling stage, and a static eliminator disposed on a side of the peeling stage;
placing the carrier, in which the substrate tray and a substrate on an electrostatic chuck of the substrate tray are accommodated, on the transport unit;
rotating the peeling stage with respect to a first side of the peeling stage facing the carrier in the first rotation direction so that a second side of the peeling stage opposite to the first side is lifted in the upward direction;
inserting the gripper into a second hole of the substrate tray among a first hole of the substrate tray in the upstream direction and the second hole of the substrate tray in the downstream direction;
overlapping the gripper and a lower surface of the substrate by moving the gripper inserted into the second hole in the upstream direction within the second hole;
opening a first clamp and a second clamp of the substrate tray to release a constraining force of the first clamp and the second clamp applied to a first side of the substrate and a second side of the substrate;
lifting the first side of the substrate from the electrostatic chuck through the gripper by moving the gripper out of the second hole by raising the support; and
providing ions between the electrostatic chuck and the substrate through a nozzle of the static eliminator, which is disposed at an edge of the peeling stage in the upstream direction.

19. The peeling method of claim 18, further comprising moving the substrate on the electrostatic chuck to the peeling stage by moving the carrier in a direction toward the second side of the peeling stage and the support along the downstream direction.

20. An electronic device comprising:
a display device, and
wherein a peeling device for the display device comprises:
a transport unit;
a carrier movable on and along the transport unit and having a substrate tray accommodated therein;
a rotatable peeling stage disposed on the transport unit;
a support disposed on the peeling stage and movable on the peeling stage along an upstream direction of the transport unit, a downstream direction of the transport unit, a downward direction toward the peeling stage, and an upward direction opposite to the downward direction, and rotatable in a first rotation direction, and a second rotation direction opposite to the first rotation direction;
a gripper connected to the support so as to be disposed between the support and the peeling stage; and
a static eliminator disposed on a side of the peeling stage.
